(19) United States
(12) Patent Application Publication
(10) Pub. No.: US 2017/0338179 A1
(43) Pub. Date: Nov. 23, 2017

(54) DEVICE PACKAGE WITH WIRE BOND ASSISTED GROUNDING AND INDUCTORS

(71) Applicant: QUALCOMM Incorporated, San Diego, CA (US)

(72) Inventors: Paragkumar Ajaybhai THADESAR, San Diego, CA (US); Young Kyu SONG, San Diego, CA (US); John Jong-Hoon LEE, San Diego, CA (US); Sangjo CHOI, San Diego, CA (US)

(21) Appl. No.: 15/161,126

(22) Filed: May 20, 2016

(51) Int. Cl. H01L 23/522; H01L 21/56; H01L 23/31; H01L 23/00

(52) U.S. Cl. CPC H01L 23/5227; H01L 24/49; H01L 24/85; H01L 21/565; H01L 24/09; H01L 23/3114; H01L 2224/04042

(57) ABSTRACT

Low inductance to ground can be provided in wire-bond based device packages. An example device package may include a die on a package substrate, a mold on the package substrate and encapsulating the die, an upper ground conductor on the mold, and ground wire bonds within the mold. The die may include a plurality of terminals on an upper surface of the die. The plurality of ground wire bonds may electrically couple the die and the upper ground conductor. For each ground wire bond, a first end of that ground wire bond may be configured to electrically couple to a corresponding terminal on the upper surface of the die and a second end of that ground wire bond may be configured to electrically couple to the upper ground conductor at the upper surface of the mold.

### FIELD OF DISCLOSURE

One or more aspects of this disclosure relate generally to device packages. In particular, one or more aspects of this disclosure relate to device packages with wire bond assisted grounding and inductors.

### BACKGROUND

Wire bond based devices are widely used for a large number of applications including digital, analog and RF (radio frequency). FIG. 1 illustrates a perspective view of a conventional wire bond device package 100. As seen, the device package 100 includes a die 100, a plurality of wire bonds 120, a ground conductor 170, and a plurality of contact pads 140. So as to minimize clutter, not all wire bonds and not all contact pads are numbered. As seen, some wire bonds 120 connect the die 110 with the ground connector 170, and other wire bonds 120 connect the die 110 with the contact pads 140.

There can be many wire bonds 120, and a significant number of them can be connected to the ground connector 170. Also, the wire bonds 120 are of different lengths. For example, the wire bonds 120 emanating from a center of the die 110 are generally longer than the wire bonds 120 emanating from a periphery of the die 110. Due to the different lengths of the wire bonds 120, there can be a huge range of wire bond inductances. Normally, such inductances are not desirable. Hence, they are referred to as “parasitic” inductances. Some parasitic inductance can be quite large, e.g., upto 2000 pH (picohenries) and more.

FIG. 2 illustrates a side view conventional device package 200 that addresses such parasitic inductance problem. The device package 200 includes a die 210, a plurality of wire bonds 220, a ground conductor 270, and a plurality of contact pads 240. The device package 200 also includes a plurality of terminals 215 on an upper surface of the die 210, a die substrate 250 between the die 210 and the ground conductor 270, a plurality of through-silicon-vias (TSVs) 225 in the die substrate 250, a package substrate 280 below the ground conductor 270, and a mold 260 on the package substrate 280.

In the device package 200, the connections between the die 210 and the ground conductor 270 is accomplished with the TSVs 225. This can shorten the connection length between the die 210 and ground, and as a result, parasitic inductance can be significantly reduced. However, the device package 200 can be costly. This is because additional process or processes to incorporate the TSVs 225 is implemented.

### SUMMARY

This summary identifies features of some example aspects, and is not an exclusive or exhaustive description of the disclosed subject matter. Whether features or aspects are included in, or omitted from this summary is not intended as indicative of relative importance of such features. Additional features and aspects are described, and will become apparent to persons skilled in the art upon reading the following detailed description and viewing the drawings that form a part thereof.

An exemplary device package is disclosed. The device package may comprise a die on a package substrate, a mold also on the package substrate, an upper ground conductor on an upper surface of the mold, and a plurality of ground wire bonds within the mold. The die may comprise a plurality of terminals on an upper surface of the die. The mold may encapsulate the die. The plurality of ground wire bonds may electrically couple the die and the upper ground conductor. For each of the plurality of ground wire bonds, a first end of that ground wire bond may be electrically coupled to a corresponding terminal on the upper surface of the die, and a second end of that ground wire bond may be electrically coupled to the upper ground conductor at the upper surface of the mold.

An exemplary method of forming device package is disclosed. The method may comprise forming a die on a package substrate. The die may comprise a plurality of terminals on an upper surface of the die. The method may also comprise forming a mold on the package substrate. The mold may be formed so as to encapsulate the die. The method may further comprise forming an upper ground conductor on an upper surface of the mold. The method may further comprise forming a plurality of ground wire bonds within the mold such that the plurality of ground wire bonds electrically couple the die and the upper ground conductor. The plurality of ground wire bonds may be formed such that for each of the plurality of ground wire bonds, a first end of that ground wire bond is electrically coupled to a corresponding terminal on the upper surface of the die and a second end of that ground wire bond is electrically coupled to the upper ground conductor at the upper surface of the mold.

An exemplary device package is disclosed. The device package may comprise a die on a package substrate, a mold also on the package substrate, an upper ground conductor on an upper surface of the mold, and a wire bond inductor within the mold. The die may comprise a plurality of terminals on an upper surface of the die. The mold may encapsulate the die. The wire bond inductor may comprise a first wire bond, an inductance pad below an upper surface of the die, a second wire bond. A first end of the first wire bond may be electrically coupled to a terminal of the die. A second end of the first wire bond may be electrically coupled to the inductance pad. A first end of the second wire bond may be electrically coupled to the inductance pad. A second end of the second wire bond may be at the upper surface of the mold.

An exemplary device package is disclosed. The device package may comprise a die on a package substrate, means for encapsulating also on the package substrate, means for grounding on an upper surface of the means for encapsulating, and a plurality of ground wire bonds within the means for encapsulating. The die may comprise a plurality of terminals on an upper surface of the die. The means for encapsulating may encapsulate the die. The plurality of ground wire bonds may electrically couple the die and the means for grounding. For each of the plurality of ground wire bonds, a first end of that ground wire bond may be electrically coupled to a corresponding terminal on the upper surface of the die, and a second end of that ground wire bond may be electrically coupled to the means for grounding at the upper surface of the mold.

### BRIEF DESCRIPTION OF THE DRAWINGS

The accompanying drawings are presented to aid in the description of embodiments and are provided solely for illustration of the embodiments and not limitation thereof.

FIG. 1 illustrates a perspective view of a conventional wire bond device package;

FIG. 2 illustrates a cross-sectional view of a conventional device package that incorporates wire bonds and through-silicon-vias;

FIG. 3 illustrates an example of a device package with wire bonds;

FIG. 4 illustrates a top view of an example of a die of a device package;

FIG. 5 illustrates a perspective view of an example of a terminal-ground wire bond inductor;

FIG. 6 illustrates a perspective view of an example of a terminal-terminal wire bond inductor;

FIGS. 7A-7D illustrate examples of stages of forming a device package with wire bonds;

FIG. 8 illustrates a flow chart of an example method to manufacture a device package with wire bonds; and

FIG. 9 illustrates examples of devices with device packages integrated therein.

### DETAILED DESCRIPTION

Examples are disclosed in the following description and related drawings directed to specific embodiments of one or more aspects of the present disclosure. Alternate embodiments may be devised without departing from the scope of the discussion. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

As mentioned, wire bond based device packages are widely used for a large number of applications. A large number of wire bonds can be provided between a device package and ground. Unfortunately, conventional wire bonds may have large parasitic inductances, which is undesirable. This can be addressed by using through-silicon vias (TSVs) for ground. Unfortunately, incorporating TSVs adds costs, which is also undesirable.

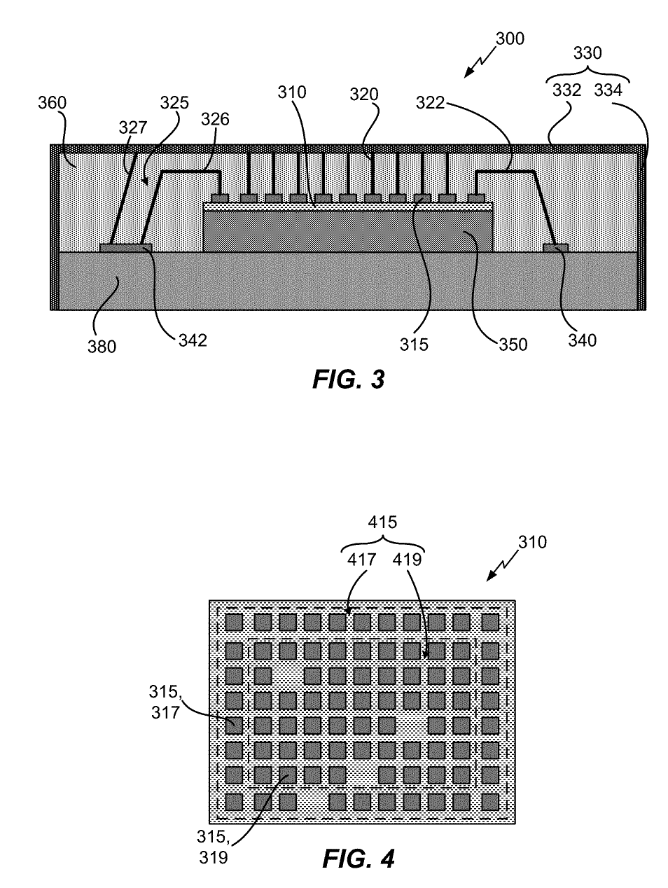

FIG. 3 illustrates an example of a device package 300 that addresses some or all problems associated with the conventional device packages. The device package 300 may include a die 310 on a package substrate 380. The die 310 may comprise a plurality of terminals 315 on an upper surface of the die 310. The device package 300 may include a mold 360 also on the package substrate 380 encapsulating the die 310. The mold 360 may be an example of a means for encapsulating. The device package 300 may further include a ground conductor 330. The ground conductor 330 may include an upper ground conductor 332 on an upper surface of the mold 360. The upper ground conductor 332 may be a plane. The ground conductor 330 may also include side ground conductor(s) 334 on side surfaces of the mold 360 and/or side surfaces of the package substrate 380. One or both of the upper ground conductor 332 and the side ground conductor(s) may be examples of means for grounding. The upper ground conductor 332 and the side ground conductor(s) 334 may also act as a shield.

The device package 300 may further include a plurality of ground wire bonds 320. The plurality of ground wire bonds 320 may be within the mold 360 and may electrically couple the die 310 and the upper ground conductor 332. Each ground wire bond 320 may correspond with one of the terminals 315 on the upper surface of the die 310. That is, for each ground wire bond 320, a first end of that ground wire bond 320 may be electrically coupled to (e.g., in contact with) a corresponding terminal 315 and a second end of that ground wire bond 320 may be electrically coupled to (e.g., in contact with) the upper ground conductor 332 at the upper surface of the mold 360. In this way, the plurality of ground wire bonds 320 may provide paths to ground from the die 310.

Some ground wire bonds 320 may be substantially vertical. Preferably, each of the plurality of ground wire bonds 320 is substantially vertical. This is preferred since this would result in the length of the ground wire bonds 320 being as short as possible, which in turn reduces parasitic inductance. When compared to the conventional device package 200 illustrated in FIG. 2, the device package 300 of FIG. 3 can be less expensive since the cost of implementing additional process(es) to incorporate the TSVs to ground can be avoided while achieving similar or better reduction in parasitic inductance.

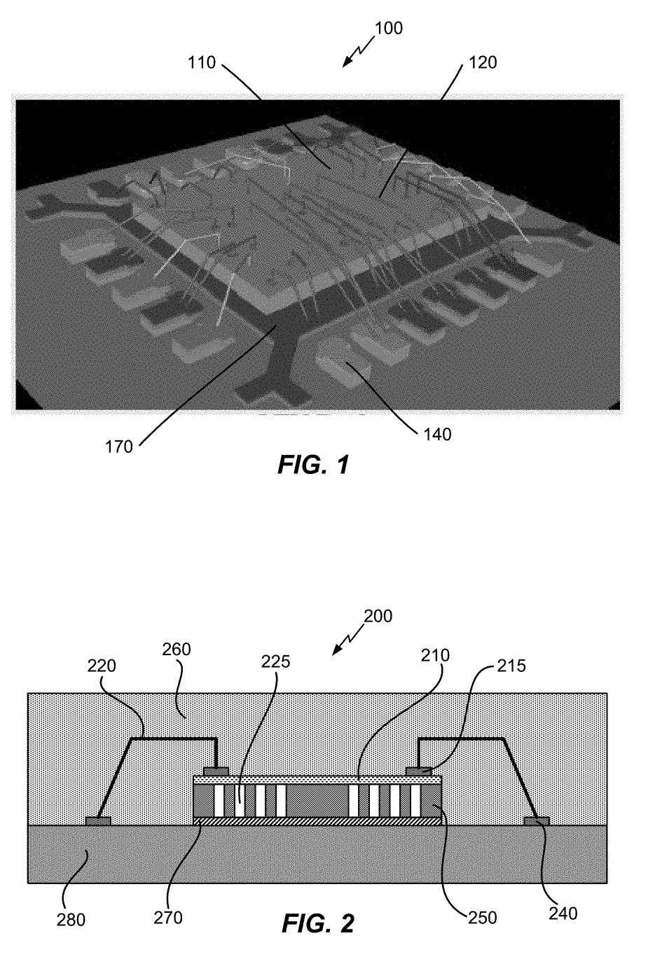

Note that unlike the conventional device package 100 illustrated in FIG. 1, the locations of the ground wire bonds 320 of the device package 300 have little to no influence on the amount of parasitic inductance. That is, the inductances of the ground wire bonds 320 emanating from a periphery of the die 310 and the inductances of the ground wire bonds 320 emanating from an interior of the die 310 can be the same or substantially the same. This is because the lengths of the ground wire bonds 320, whether emanating from the periphery or from the interior of the die 310, can be formed to be substantially equal. Also, by controlling the separation between the upper ground conductor 332 and the upper surface of the die 310, the actual inductances of the ground wire bonds 320 can be controlled, at least to some degree.

A corollary of the above-indicated advantage of the device package 300 is that some, i.e., one or more, of the ground wire bonds 320 can emanate from the interior of the die 310 and still have reduced parasitic inductance. This is explained with reference to FIG. 4 which illustrates a top view of the die 310. In particular, FIG. 4 illustrates an example arrangement of the terminals 315. As seen, the terminals 315 may be arranged as an array, referred to as a terminal array 415 for convenience. Thus, from one perspective, it may be said that the terminal array 415 comprises the plurality of terminals 315.

The terminal array 415 may be divided into a peripheral array 417 and an interior array 419 in which the peripheral array 417 surrounds the interior array 419. In FIG. 4, an area within the inner dashed box may represent the interior array 419, and an area between the inner and outer dashed boxes may represent the peripheral array 417. For convenience, each terminal 315 within the peripheral array 417 may also be referred to as a peripheral terminal 317. In other words, the peripheral array 417 may include one or more peripheral terminals 317 in which each peripheral terminal 317 is also one of the plurality of terminals 315. Also for convenience, each terminal 315 within the interior array 419 may also be referred to as an interior terminal 319. That is, the interior array 419 may include one or more interior terminals 319 in which each interior terminal 317 is also one of the plurality of terminals 315.

At least one ground wire bond 320 may correspond to an interior terminal 319 of the interior array 419 such that the first end of that ground wire bond 320 is in contact with the corresponding interior terminal 319 on the upper surface of the die 310. Of course, it is also within the scope of the disclosure that there are ground wire bond(s) 320 corresponding to peripheral terminal(s) 319. To reiterate, it is possible to have a ground wire bond 320 emanate from the interior of the die 310, i.e., correspond to an interior terminal 319, because the reduced parasitic inductance can be achieved substantially independently of the location of the ground wire bond 320.

It should be noted that the arrangement illustrated in FIG. 4 should not be taken to be limiting. For example, the arrangement of the terminal array 415 need not be a rectangle. Also, the terminals 315 need not be regularly spaced apart. In addition, not all terminals 315 must correspond to the ground wire bonds 320. That is, some of the interior terminals 319 may not be coupled to a ground wire bond 320. Similar statement may be made about the peripheral terminals 317. Moreover, the peripheral array 417 need not be limited to the outermost terminals 315.

Referring back to FIG. 3, the device package 300 may additionally include a substrate die 350, one or more package wire bonds 322, and one or more contact pads 340. The mold 360 may encapsulate some of all of the substrate die 350, the package wire bond(s) 322, and the contact pad(s) 340. Each package wire bond 322 may electrically couple one of the terminals 315 with one of the contact pads 340. As an aside, another benefit of the device package 300 is that it can provide improved isolation due to the close physical distance between the upper ground conductor 332 and the package wire bonds 322.

Recall from above that one significant advantage (of which there can be several) of the device package 300 is that the parasitic inductance can be reduced. However, there may be applications, e.g., degeneration applications, where high inductances are desirable. These include power amplifiers and low noise amplifiers. In FIG. 3, the device package 300 may include one or more wire bond inductors (WBI) 325, which may be within the mold 360, to provide increased inductances for such applications. Each WBI 325 may include one or more first wire bonds 326, one or more inductance pads 342, and one or more second wire bonds 327. The first wire bond 326 may be electrically coupled to the second wire bond 327 via the inductance pad 342 which may be conductive. The first wire bond 326 may be electrically coupled to (e.g., in contact with) one of the terminals 315 on the upper surface of the die 310.

FIG. 3 illustrates both ground wire bonds 320 and the WBIs 325 in the device package 300. However, this not should be taken to be limiting. Any combination of the ground wire bonds 320 and WBIs 325 are within the scope of this disclosure.

The WBIs 325 may include at least the following two types—terminal-ground (TG) and terminal-terminal (TT). One or both of types of WBIs 325 may serve as off-chip inductors that can replace on-chip inductors for achieving higher inductance values with improved Q factors.

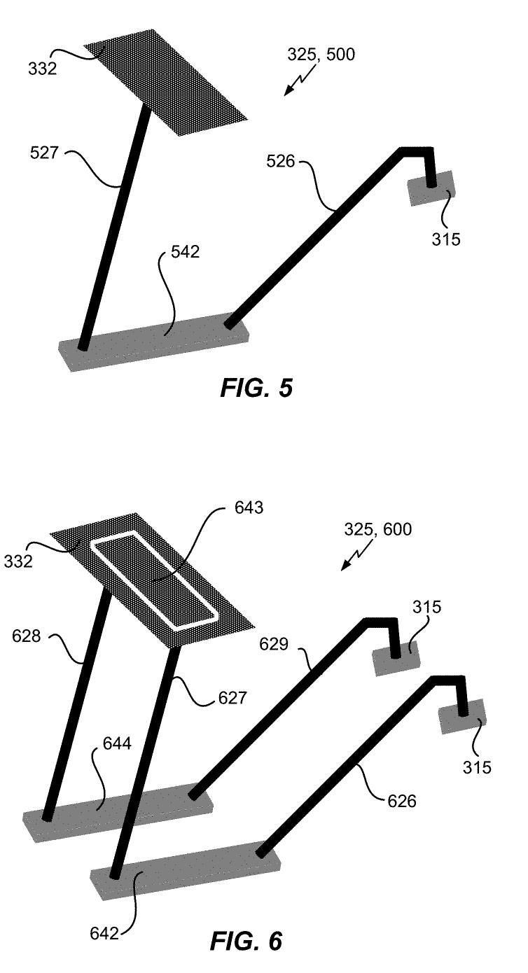

FIG. 5 illustrates a perspective view of an example of a terminal-ground WBI 500 whose first end is electrically coupled to one of the terminals 315 and whose second end is electrically coupled to ground. The terminal-ground WBI 500 may include a first wire bond 526, an inductance pad 542, and a second wire bond 527. The inductance pad 542, which is conductive, may be made from a material or materials same or similar to the contact pad 340.

The electrical couplings of the terminal-ground WBI 500 may be as follows: terminal 315⇄first wire bond 526⇄inductance pad 542⇄second wire bond 527⇄upper ground conductor 332. That is, for the first wire bond 526, a first end thereof may be electrically coupled to (e.g., in contact with) the terminal 315, and a second end thereof may be electrically coupled to (e.g., in contact with) the inductance pad 542. For the second wire bond 527, a first end thereof may be electrically coupled to (e.g., in contact with) the inductance pad 542, and a second end thereof may be electrically coupled to (e.g., in contact with) the upper ground conductor 332 at the upper surface of the mold 360. So as to minimize obfuscation, only a part of the upper ground conductor 332—the part in contact with the second wire bond 527—is shown.

For convenience, the first end of the first wire bond 526 may also be the first end of the terminal-ground WBI 500, and the second end of the second wire bond 527 may also be the second end of the terminal-ground WBI 500. With the first and second ends of the terminal-ground WBI 500 so defined, the following characterizations may be made. First, a portion of the terminal-ground WBI 500 between the first and second ends thereof may be below the terminal 315, i.e., below the upper surface of the die 310. Second, there may also be a portion of the terminal-ground WBI 500 between the first and second ends that is above the die 310. In FIG. 3, these portions may correspond to the portions of the WBI 325 below and above the die 310. In this way, a total length of the WBI 325—the terminal-ground WBI 500—may be increased, which in turn can increase inductance and thereby improve Q factors of the terminal-ground WBI 500. By controlling the amounts of the portions above and/or below the die 310, the inductance of the terminal-ground WBI 500 may be controlled at least to some degree. Regarding the portion below the die 310, a part may be on the package substrate 380. For example, the inductance pad 542 may be on the upper surface of the package substrate 380 similar to the contact pads 340.

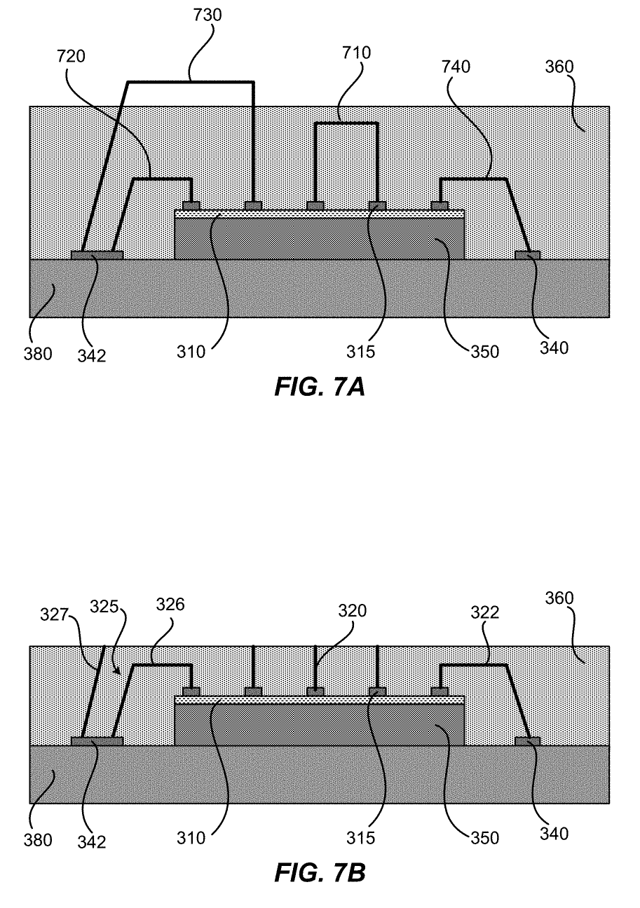

FIG. 6 illustrates a perspective view of an example of a terminal-terminal WBI 600 whose first end is electrically coupled to one of the terminals 315 (first terminal 315) and whose second end is electrically coupled to another of the terminals 315 (second terminal 315). The terminal-terminal WBI 600 may include first, second, third, and fourth wire bonds 626, 627, 628, 629, and first, second, and third inductance pads 642, 643, 644. The first and third inductance pads 642, 644, which are conductive, may be made from a material or materials same or similar to the contact pad 340. The second inductance pad 643, which is also conductive, may be made from a material or materials same or similar to the upper ground conductor 332. However, the second inductance pad 643 may be electrically isolated from the upper ground conductor 332. For example, the upper ground conductor 332 may be etched to form the second inductance pad 643. So as to minimize obfuscation, only a part of the upper ground conductor 332—the part that surrounds the second inductance pad 643—is shown.

The electrical couplings of the terminal-terminal WBI 600 may be as follows: first terminal 315⇄first wire bond 626⇄first inductance pad 642⇄second wire bond 627⇄second inductance pad 643⇄third wire bond 628⇄third inductance pad 644⇄fourth wire bond 629⇄second terminal 315. That is, for the first wire bond 626, a first end thereof may be electrically coupled to (e.g., in contact with) the first terminal 315, and a second end thereof may be electrically coupled to (e.g., in contact with) the first inductance pad 642. For the second wire bond 627, a first end thereof may be electrically coupled to (e.g., in contact with) the first inductance pad 642, and a second end thereof may be electrically coupled to (e.g., in contact with) the second inductance pad 643 at the upper surface of the mold 360. For the third wire bond 628, a first end thereof may be electrically coupled to (e.g., in contact with) the second inductance pad 643, and a second end thereof may be electrically coupled to (e.g., in contact with) the third inductance pad 644. For the fourth wire bond 629, a first end thereof may be electrically coupled to (e.g., in contact with) the third inductance pad 644, and a second end thereof may be electrically coupled to (e.g., in contact with) the second terminal 315. The first terminal 315 and the second terminal 315 may be two different terminals 315 of the die 310. While not shown, it is within the scope of the disclosure that the first and second terminals 315 are terminals of different dies 310.

For convenience, the first end of the first wire bond 626 may also be the first end of the terminal-terminal WBI 600, and the second end of the fourth wire bond 629 may also be the second end of the terminal-terminal WBI 600. First, a portion of the terminal-terminal WBI 600 between the first and second ends may be below the upper surface of the die 310. Second, there may also be a portion of the terminal-terminal WBI 600 between the first and second ends that is above the die 310. In FIG. 3, these portions may correspond to the portions of the WBI 325 below and above the die 310. In this way, a total length of the WBI 325—the terminal-terminal WBI 600—may be increased, which in turn can increase inductance and thereby improve Q factors of the terminal-terminal WBI 600. By controlling the amounts of the portions above and/or below the die 310, the inductance of the terminal-terminal WBI 600 may be controlled at least to some degree. Regarding the portion below the die 310, a part may be on the package substrate 380. For example, one or both of the first and third inductance pads 642, 644 may be on the upper surface of the package substrate 380 similar to the contact pads 340.

While not illustrated, it is within the scope of this disclosure that first and third inductance pads be electrically coupled directly via one wire bond instead of the second wire bond 627, the second inductance pad 643, and the third wire bond 628. Such terminal-terminal WBI may be simpler to manufacture. The tradeoff may be that not as much inductance as the terminal-terminal WBI 600 may be provided.

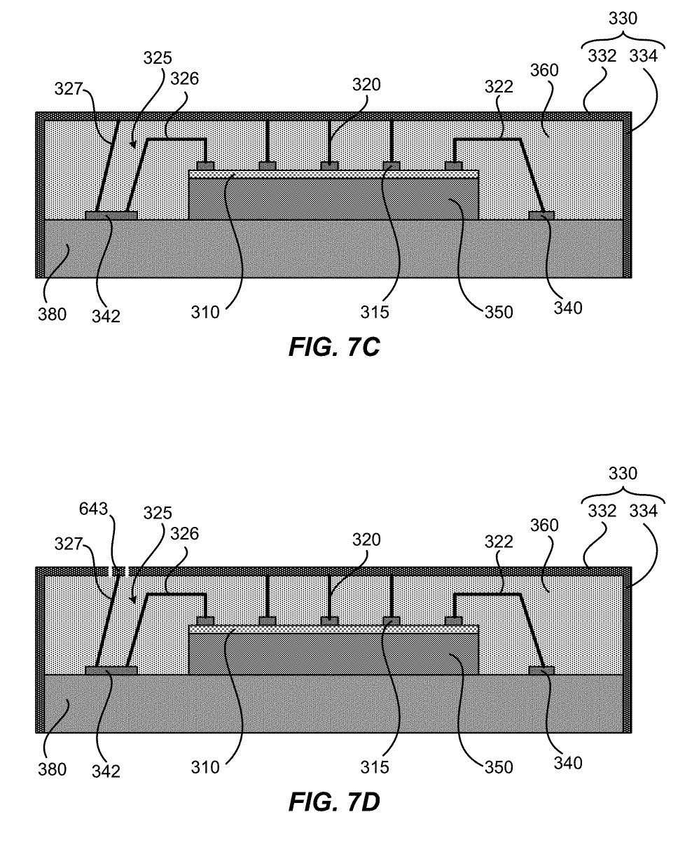

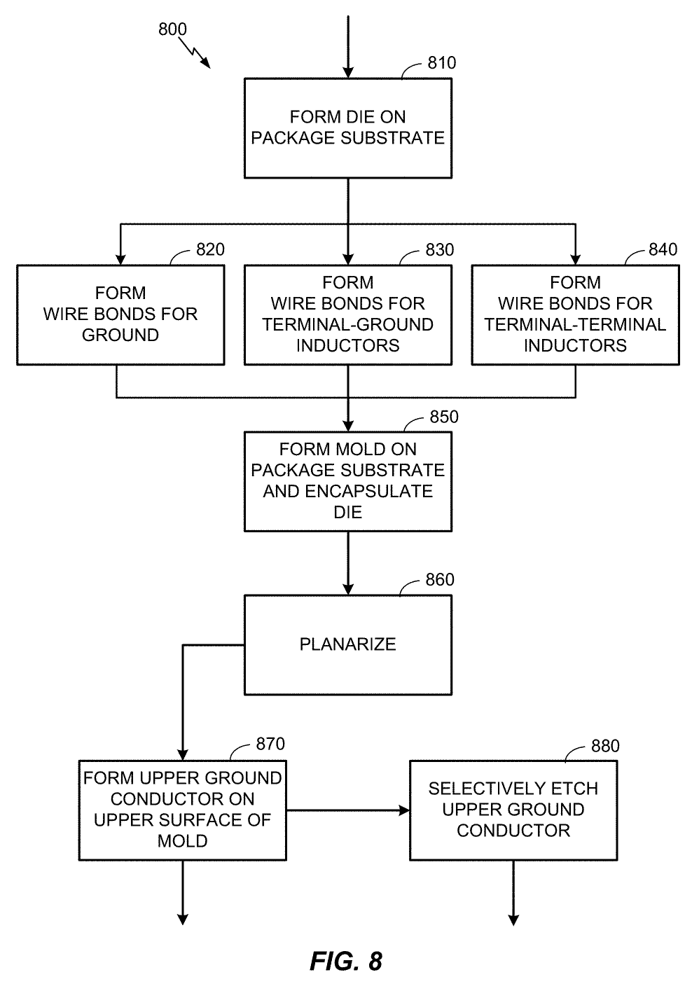

FIGS. 7A-7D illustrate examples of different stages of forming a device package with wire bonds such as the device package 300. FIG. 7A-7C are not necessarily exhaustive. For ease of visualization of the stages, the number of terminals 315 included in these figures has been reduced relative to FIG. 3. However, this should not detract from the scope.

FIG. 7A illustrates a stage prior to planarization. At this pre-planarization stage, the package substrate 380 may be formed; the contact pads 340, the inductance pads 342 (e.g., the inductance pads 542, first inductance pads 642, and/or third inductance pads 644), the die substrate 350, and the die 310 with the plurality of terminals 315 may be formed on the package substrate 380; initial wire bonds 710, 720, 730, 740 may be formed; and the encapsulating mold 360 may be deposited on the package substrate 380. The ends of the initial wire bonds 710, 720, 730, 740 may be coupled to (e.g., in contact with) any of the terminals 315, the contact pads 340, the inductance pads 342 and/or the plurality of terminals 315. It is possible that some initial wire bonds (e.g., the initial wire bond 730) are not completely encapsulated after the deposition of the mold 360. While not illustrated, it is also possible that the mold 360 can be thick enough to encapsulate all wire bonds including the tall initial wire bond 730. This indicates that while it is possible to do so, it is NOT required to completely encapsulate all initial wire bonds 710, 720, 730, 740 prior to planarizing. In an aspect, regardless of whether some or all initial wire bonds 710, 720, 730, 740 are encapsulated before planarization, the result should be substantially the same after planarization.

FIG. 7B illustrates a stage after planarizing the mold 360 to a desired height, also referred to as the threshold height. At this stage, the ground wire bonds 320, the package wire bonds 322, and/or the wire bonds 326, 327 (e.g., the first, second, third, and/or fourth wire bonds 526, 527, 626, 627, 628, 629) may be formed from the initial wire bonds 710, 720, 730, 740. The second ends of the ground wire bonds 320 and/or the second ends of the wire bonds 327 (e.g., the second ends of the second and/or third wire bonds 527, 627, 628) may be exposed at the upper surface of the mold 360.

FIG. 7C illustrates a stage after a conductive material or materials, e.g., copper, may be deposited on the mold 360 to form the upper ground conductor 332. After the conductive material deposition, the die 310 may be coupled to the upper ground conductor 332 via the ground wire bonds 320. Also after the deposition, the terminal-ground WBI 500 may be electrically coupled to the upper ground conductor 332. Note that the conductive material may also be deposited on the sides of the mold 360 and/or the package substrate 380 to form the ground side conductors 334. The conductive material may be planarized after the deposition so that the upper ground conductor 332 is planar.

FIG. 7D illustrates a stage in which the terminal-terminal WBI 600 of FIG. 6 may be formed. After the upper ground conductor 332 is formed, the second inductance pads 643 may be formed through selective etching of the upper ground conductor 332. The etching may be performed so as to electrically isolate the second inductance pads 643 from the upper ground conductor 332. Note that if no terminal-terminal WBIs 600 is formed, then the processing stage illustrated in FIG. 7D need not be performed.

FIG. 8 illustrates a flow chart of an example method 800 to manufacture a device package with wire bonds. In block 810, a die 310 may be formed on a package substrate 380. In block 820, wire bonds for the ground wire bonds 320 may be formed. These may correspond to forming the initial wire bonds 710 and/or 720. See FIG. 7A. Each of the initial wire bonds 710 and/or 730 may be coupled to (e.g., in contact with) a terminal 315 and extend to a height at or above the threshold height. See also FIG. 7B.

In block 830, wire bonds for one or more terminal-ground WBIs 325, 500 may be formed. For each terminal-ground WBI 500, this may correspond to forming a pair of initial wire bonds 720 and 730. See FIG. 7A. For the purpose of describing this block 830, the initial wire bond 720 will be referred to as the first initial wire bond 720, and the initial wire bond 730 will be referred to as the second initial wire bond 730. Then the first initial wire bond 720 of the pair may be electrically coupled to (e.g., in contact with) a terminal 315 on one end and electrically coupled to (e.g., in contact with) the inductance pad 542 on another end. Also, the second initial wire bond 730 of the pair may be electrically coupled to (e.g., in contact with) the inductance pad 542 and extend to a height at or above the threshold height. See also FIGS. 7B and 5.

In block 840, wire bonds for one or more terminal-terminal WBIs 325, 600 may be formed. For each terminal-ground WBI 500, this may correspond to forming a group of two initial wire bonds 720 and two initial wire bonds 730. For the purpose of describing this block 840, one initial wire bond 720 will be referred to as the first initial wire bond 720, and the other will be referred to as the fourth initial wire bond 720. Also, one initial wire bond 730 will be referred to as the second initial wire bond 730, and the other will be referred to as the third initial wire bond 730. Then the first initial wire bond 720 of the group may be electrically coupled to (e.g., in contact with) a first terminal 315 on one end and electrically coupled to (e.g., in contact with) the first inductance pad 642 on another end. The second initial wire bond 730 of the group may be electrically coupled to (e.g., in contact with) the first inductance pad 642 and extend to a height at or above the threshold height. The third initial wire bond 730 of the group may be electrically coupled to (e.g., in contact with) the third inductance pad 644 and extend to a height at or above the threshold height. The fourth initial wire bond 720 of the group may be electrically coupled to (e.g., in contact with) the second terminal 315 on one end and electrically coupled to (e.g., in contact with) the third inductance pad 644 on another end. See also FIGS. 7B and 6.

It is not necessary to perform all of the blocks 820, 830, and 840. For example, if no terminal-terminal WBIs 600 are necessary, then block 840 need not be performed. This implies that the ground wire bonds 320, the terminal-ground WBIs 500, and the terminal-terminal WBIs 600 can be formed independently of each other.

Further, if and when any two or all three of the blocks 820, 830, and 840 are to be performed, they may be performed contemporaneously. As an illustration, if it is assumed that ground wire bonds 320 and terminal-ground WBIs 500 are to be formed, it is not necessary to completely perform block 820 before starting on block 830 or vice versa. In one aspect, the blocks may be performed simultaneously. In another aspect, a back-and-forth approach may be used, e.g., some wire bonds may be initially formed for the ground wire bonds 320 followed by forming some wire bonds for the terminal-ground WBIs 500, then followed by forming other wire bonds for the ground wire bonds 320, and so forth. The back-and-forth approach may be advantageous when routing of the initial wire bonds are taken into consideration.

In block 850, the mold 360 may be formed on the package substrate 380 so as to encapsulate the die 310. As seen in FIG. 7A, some or all of the wire bonds 710, 720, 730, 740 formed in blocks 820, 830, and/or 840 may also be encapsulated by the mold 360.

In block 860, the mold 360 may be planarized to the threshold height as seen in FIG. 7B. If block 820 is performed, then in block 860, the ground wire bonds 320 with short lengths (and hence reduced parasitic inductance) can be formed. Also, the second ends of the ground wire bonds 320 may be exposed. If block 830 is performed, then in block 860, the second ends of the second wire bonds 527 may be exposed. If block 840 is performed, then in block 860, the second ends of the second wire bonds 627 and the first ends of the third wire bonds 628 may be exposed may be exposed.

In block 870, a conductive material, e.g., copper, may be deposited on the mold 360 (and planarized if desired) to form the upper ground conductor 332 as seen in FIG. 7C. The ground side conductors 334 may also be formed. If block 820 is performed, then in block 870, the ground wire bonds 320 may be electrically coupled to the upper ground conductor 332. For example, the second ends ground wire bonds 320 exposed in block 860 may contact the deposited conductive material. If block 830 is performed, then in block 870, the second ends of the second wire bonds 527 may be electrically coupled to (e.g., in contact with) the upper ground conductor 332. See also FIG. 5. If block 840 is performed, then in block 870, the second ends of the second wire bonds 627 and the first ends of the third wire bonds 628 may be electrically coupled to (e.g., in contact with) the upper ground conductor 332 which will be selectively etched.

If block 840 is performed, then in block 880, the upper ground conductor 332 may be selectively etched to form the second inductance pads 643 as seen in FIGS. 7D and 6. The etched portions, i.e., the second inductance pads 643, may be electrically isolated from the remaining upper ground conductor 332.

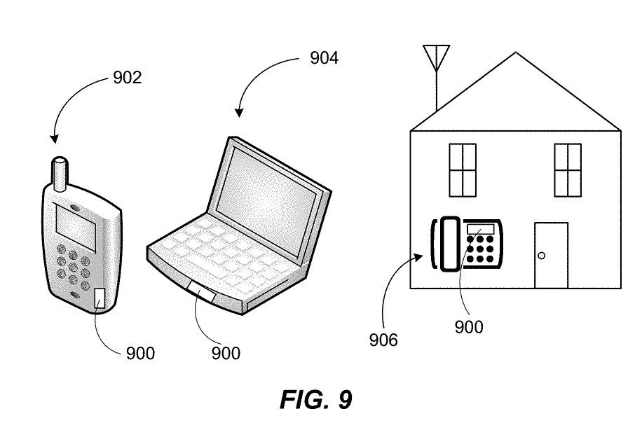

FIG. 9 illustrates various electronic devices that may be integrated with any of the aforementioned device packages. For example, a mobile phone device 902, a laptop computer device 904, and a fixed location terminal device 906 may include an integrated device 900 as described herein. The integrated device 900 may be, for example, any of the device packages described herein. The devices 902, 904, 906 illustrated in FIG. 9 are merely exemplary. Other electronic devices may also feature the integrated device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the embodiments disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment can include a computer readable media embodying a method of forming a device package. Accordingly, the scope of the disclosed subject matter is not limited to illustrated examples and any means for performing the functionality described herein are included.

While the foregoing disclosure shows illustrative embodiments, it should be noted that various changes and modifications could be made herein without departing from the scope of the disclosed subject matter as defined by the appended claims. The functions, processes and/or actions of the method claims in accordance with the embodiments of the disclosed subject matter described herein need not be performed in any particular order. Furthermore, although elements of the disclosed subject matter may be described or claimed in the singular, the plural is contemplated unless limitation to the singular is explicitly stated.

1. A device package, comprising:
a die on a package substrate, the die comprising a plurality of terminals on an upper surface of the die;
a mold on the package substrate and encapsulating the die;
an upper ground conductor on an upper surface of the mold; and
a plurality of ground wire bonds within the mold, the plurality of ground wire bonds configured to electrically couple the die and the upper ground conductor,
wherein for each of the plurality of ground wire bonds, a first end of that ground wire bond is configured to electrically couple to a corresponding terminal on the upper surface of the die and a second end of that ground wire bond is configured to electrically couple to the upper ground conductor at the upper surface of the mold.

2. The device package of claim 1, wherein each of the plurality of ground wire bonds is substantially vertical.

3. The device package of claim 1,
wherein the plurality of terminals are arranged as a terminal array comprising a peripheral array and an interior array, the peripheral array surrounding the interior array,
wherein the peripheral array comprises one or more peripheral terminals, each of the one or more peripheral terminals being one of the plurality of terminals,
wherein the interior array comprises one or more interior terminals, each of the one or more interior terminals being one of the plurality of terminals, and
wherein at least one ground wire bond of the plurality of ground wire bonds corresponds to an interior terminal of the interior array such that the first end of the at least one ground wire bond is configured to electrically couple to the corresponding interior terminal on the upper surface of the die.

4. The device package of claim 1, further comprising a terminal-ground wire bond inductor within the mold,
wherein a first end of the terminal-ground wire bond inductor is configured to electrically couple to a terminal of the die,
wherein a second end of the terminal-ground wire bond inductor is configured to electrically couple to the upper ground conductor, and
wherein a portion of the terminal-ground wire bond inductor between the first and second ends is below the upper surface of the die.

5. The device package of claim 4, wherein the portion of the terminal-ground wire bond inductor between the first and second ends thereof is on an upper surface of the package substrate.

6. The device package of claim 4, wherein the terminal-ground wire bond inductor comprises:
a first wire bond;
an inductance pad below the upper surface of the die; and
a second wire bond,
wherein a first end of the first wire bond is configured to electrically couple to the terminal of the die, and a second end of the first wire bond is configured to electrically couple to the inductance pad, the first end of the first wire bond serving as the first end of the terminal-ground wire bond inductor, and
wherein a first end of the second wire bond is configured to electrically couple to the inductance pad, and a second end of the second wire bond is configured to electrically couple to the upper ground conductor, the second end of the second wire bond serving as the second end of the terminal-ground wire bond inductor.

7. The device package of claim 6, wherein the inductance pad is on an upper surface of the package substrate.

8. The device package of claim 1, further comprising a terminal-terminal wire bond inductor within the mold,
wherein a first end of the terminal-terminal wire bond inductor is configured to electrically couple to a first terminal of the die,
wherein a second end of the terminal-terminal wire bond inductor is configured to electrically couple to a second terminal of the die, and
wherein a portion of the terminal-terminal wire bond inductor between the first and second ends is below the upper surface of the die.

9. The device package of claim 8, wherein the portion of the terminal-terminal wire bond inductor between the first and second ends thereof is on an upper surface of the package substrate.

10. The device package of claim 8, wherein the terminal-terminal wire bond inductor comprises:
a first wire bond;
a first inductance pad on an upper surface of the package substrate;
a second wire bond;
a second inductance pad on the upper surface of the mold;
a third wire bond;
a third inductance pad on the upper surface of the package substrate; and
a fourth wire bond,
wherein a first end of the first wire bond is configured to electrically couple to the first terminal of the die, and a second end of the first wire bond is configured to electrically couple to the first inductance pad, the first end of the first wire bond serving the first end of the terminal-terminal wire bond inductor,
wherein a first end of the second wire bond is configured to electrically couple to the first inductance pad, and a second end of the first wire bond is configured to electrically couple to the second inductance pad,
wherein a first end of the third wire bond is configured to electrically couple to the second inductance pad, and a second end of the third wire bond is configured to electrically couple to the third inductance pad, and
wherein a first end of the fourth wire bond is configured to electrically couple to the third inductance pad, and a second end of the fourth wire bond is configured to electrically couple to the second terminal of the die, the second end of the fourth wire bond serving as the second end of the terminal-terminal wire bond inductor.

11. The device package of claim 10, wherein at least one of the first inductance pad and the third inductance pad is on an upper surface of the package substrate.

12. The device package of claim 10, wherein the second inductance pad is on the upper surface of the mold and electrically isolated from the upper ground conductor.

13. A method of forming a device package, the method comprising:
forming a die on a package substrate, the die comprising a plurality of terminals on an upper surface of the die;
forming a mold on the package substrate and so as to encapsulate the die;
forming an upper ground conductor on an upper surface of the mold; and
forming a plurality of ground wire bonds within the mold to electrically couple the die and the upper ground conductor,
wherein forming the plurality of ground wire bonds comprises forming, for each of the plurality of ground wire bonds, a first end of that wire bond to electrically
wherein forming the plurality of ground wire bonds comprises forming, for each of the plurality of ground wire bonds, a first end of that ground wire bond to electrically couple to a corresponding terminal on the upper surface of the die and a second end of that ground wire bond to electrically couple to the upper ground conductor at the upper surface of the mold.

14. The method of claim 13, wherein forming the plurality of ground wire bonds comprises:
prior to forming the mold, forming one or more initial wire bonds; and
subsequent to forming the mold and prior to forming the upper ground conductor, planarizing the mold to a threshold height,
wherein forming the one or more initial wire bonds comprises forming, for each of the one or more initial wire bonds, that initial wire bond to electrically couple to one of the plurality of terminals and extend to a height at or above the threshold height.

15. The method of claim 13, wherein forming the plurality of ground wire bonds comprises forming each of the plurality of ground wire bonds to be substantially vertical.

16. The method of claim 13,
wherein the plurality of terminals are arranged as a terminal array comprising a peripheral array and an interior array, the peripheral array surrounding the interior array,
wherein the peripheral array comprises one or more peripheral terminals, each peripheral terminal being one of the plurality of terminals,
wherein the interior array comprises one or more interior terminals, each interior terminal being one of the plurality of terminals, and
wherein forming the plurality of ground wire bonds comprises forming, for at least one ground wire bond of the plurality of ground wire bonds that corresponds to an interior terminal of the interior array, the first end of that ground wire bond to electrically couple to the corresponding interior terminal on the upper surface of the die.

17. The method of claim 13, further comprising forming a terminal-ground wire bond inductor within the mold, wherein forming the terminal-ground wire bond inductor comprises:
forming a first wire bond;
forming an inductance pad on an upper surface of the package substrate; and
forming a second wire bond,
wherein forming the first wire bond comprises forming a first end of the first wire bond to electrically couple to a terminal of the plurality of terminals, and a second end of the first wire bond to electrically couple to the inductance pad, and
wherein forming the second wire bond comprises forming a first end of the second wire bond to electrically couple to the inductance pad, and a second end of the second wire bond to electrically couple to the upper ground conductor.

18. The method of claim 17, wherein forming the terminal-ground wire bond inductor comprises:
prior to forming the mold, forming a pair of initial wire bonds, the pair comprising first and second initial wire bonds; and
subsequent to forming the mold and prior to forming the upper ground conductor, planarizing the mold to a threshold height,
wherein forming the pair of initial wire bonds comprises:
forming the first initial wire bond of the pair to electrically couple to the terminal on one end and to electrically couple to the inductance pad on another end; and
forming the second initial wire bond of the pair to electrically couple to the inductance pad and extend to a height at or above the threshold height.

19. The method of claim 17, wherein forming the terminal-ground wire bond inductor takes place contemporaneously with forming the plurality of ground wire bonds.

20. The method of claim 13, further comprising forming a terminal-terminal wire bond inductor within the mold, wherein forming the terminal-terminal wire bond inductor comprises:
forming a first wire bond;
forming a first inductance pad on an upper surface of the package substrate;
forming a second wire bond;
forming a second inductance pad on the upper surface of the mold;
forming a third wire bond;
forming a third inductance pad on the upper surface of the package substrate; and
forming a fourth wire bond,
wherein forming the first wire bond comprises forming a first end of the first wire bond to electrically couple to a first terminal of the plurality of terminals, and a second end of the first wire bond to electrically couple to the first inductance pad,
wherein forming the second wire bond comprises forming a first end of the second wire bond to electrically couple to the first inductance pad, and a second end of the first wire bond to electrically couple to the second inductance pad,
wherein forming the third wire bond comprises forming a first end of the third wire bond to electrically couple to the second inductance pad, and a second end of the third wire bond to electrically couple to the third inductance pad, and
wherein forming the fourth wire bond comprises forming a first end of the fourth wire bond to electrically couple to the third inductance pad, and a second end of the fourth wire bond to electrically couple to a second terminal of the of the plurality of terminals.

21. The method of claim 20, wherein forming the terminal-terminal wire bond inductor comprises:
prior to forming the mold, forming a group of initial wire bonds, the group comprising first, second, third, and fourth initial wire bonds; and
subsequent to forming the mold and prior to forming the upper ground conductor, planarizing the mold to a threshold height,
wherein forming the group of initial wire bonds comprises:
forming the first initial wire bond of the group to electrically couple to the first terminal on one end and to electrically couple to the first inductance pad on another end;
forming the second initial wire bond of the group to electrically couple to the first inductance pad and extend to a height at or above the threshold height;
forming the third initial wire bond of the group to electrically couple to the third inductance pad and extend to a height at or above the threshold height; and
forming the fourth initial wire bond of the group to electrically couple to the second terminal on one end and to electrically couple to the third inductance pad on another end.

22. The method of claim 20, wherein forming the terminal-terminal wire bond inductor takes place contemporaneously with forming the plurality of ground wire bonds.

23. A device package, comprising:
a die on a package substrate, the die comprising a plurality of terminals on an upper surface of the die;
means for encapsulating on the package substrate and encapsulating the die;
means for grounding on an upper surface of the means for encapsulating; and
a plurality of ground wire bonds within the means for encapsulating, the plurality of ground wire bonds electrically coupling the die and the means for grounding,
wherein for each of the plurality of ground wire bonds, a first end of that ground wire bond is configured to electrically couple to a corresponding terminal on the upper surface of the die and a second end of that ground wire bond is configured to electrically couple to the upper ground conductor at the upper surface of the mold.

24. The device package of claim 23, further comprising a wire bond inductor within the means for encapsulating, wherein the wire bond inductor comprises:
a first wire bond;
an inductance pad below an upper surface of the die; and
a second wire bond,
wherein a first end of the first wire bond is configured to electrically couple to a terminal of the die, and a second end of the first wire bond is configured to electrically couple to the inductance pad, and
wherein a first end of the second wire bond is configured to electrically couple to the inductance pad, and a second end of the second wire bond is at the upper surface of the mold.

25. A device package, comprising:
a die on a package substrate, the die comprising a plurality of terminals on an upper surface of the die;
a mold on the package substrate and encapsulating the die;
an upper ground conductor on an upper surface of the mold; and
a wire bond inductor within the mold,
wherein the wire bond inductor comprises:
a first wire bond;
an inductance pad below an upper surface of the die; and
a second wire bond,
wherein a first end of the first wire bond is configured to electrically couple to a terminal of the die, and a second end of the first wire bond is configured to electrically couple to the inductance pad, and
wherein a first end of the second wire bond is configured to electrically couple to the inductance pad, and a second end of the second wire bond is at the upper surface of the mold.

26. The device package of claim 25, wherein the second end of the second wire bond is configured to electrically couple to the upper ground conductor.

27. The device package of claim 26, wherein the inductance pad is on an upper surface of the package substrate.

28. The device package of claim 25,
wherein the terminal is a first terminal and the inductance pad is a first inductance pad,
wherein the wire bond inductor further comprises:
a second inductance pad above the upper surface of the die;
a third wire bond;
a third inductance pad below the upper surface of the die; and
a fourth wire bond,
wherein a first end of the second wire bond is configured to electrically couple to the first inductance pad, and a second end of the first wire bond is configured to electrically couple to the second inductance pad,
wherein a first end of the third wire bond is configured to electrically couple to the second inductance pad, and a second end of the third wire bond is configured to electrically couple to the third inductance pad, and
wherein a first end of the fourth wire bond is configured to electrically couple to the third inductance pad, and a second end of the fourth wire bond is configured to electrically couple to the second terminal of the die.

29. The device package of claim 28, wherein the second inductance pad is on the upper surface of the mold and electrically isolated from the upper ground conductor.

30. The device package of claim 28, wherein at least one of the first inductance pad and the third inductance pad is on an upper surface of the package substrate.
